(19) United States
(12) Patent Application Publication
(10) Pub. No.: US 2026/0092953 A1
(43) Pub. Date: Apr. 2, 2026

(54) WAVEFORM SELECTION METHOD, ELECTRONIC TEST AND MEASUREMENT DEVICE, AND STORAGE MEDIUM

(71) Applicant: RIGOL TECHNOLOGIES CO., LTD., Suzhou (CN)

(72) Inventors: Defang XUE, Suzhou (CN); Yue WANG, Suzhou (CN)

(21) Appl. No.: 19/413,385

(22) Filed: Dec. 9, 2025

Related U.S. Application Data
(63) Continuation of application No. PCT/CN2024/132885, filed on Nov. 19, 2024.

(30) Foreign Application Priority Data
Nov. 28, 2023 (CN) 202311600510.8

(51) Int. Cl. G01R 13/02; G01R 19/25

(52) U.S. Cl. CPC G01R 13/0272; G01R 13/0236; G01R 19/2509

(57) ABSTRACT

Provided are a waveform selection method, an electronic test and measurement device, and a storage medium. The waveform selection method comprises the following: in response to a click operation of a user, determining a click position on a display; determining a waveform selection region according to the click position; determining waveform energies of waveforms of a plurality of channels within the waveform selection region; and selecting a target waveform from the waveforms of the plurality of channels according to the waveform energy of the waveforms of the plurality of channels.

### CROSS-REFERENCE TO RELATED APPLICATIONS

This is a continuation of International Patent Application No. PCT/CN2024/132885, filed on Nov. 19, 2024, which claims priority to Chinese Patent Application No. 202311600510.8 filed with the China National Intellectual Property Administration (CNIPA) on Nov. 28, 2023, the disclosures of which are incorporated herein by reference in their entireties.

### TECHNICAL FIELD

The present application relates to the technical field of signal processing, for example, to a waveform selection method, an electronic test and measurement device, and a storage medium.

### BACKGROUND

A digital oscilloscope is a widely used electronic test and measurement device. The digital oscilloscope includes multiple channels for receiving signals. When the digital oscilloscope receives signals from at least one device under test, waveforms corresponding to these signals can be simultaneously displayed on the display through the respective channels.

Since the digital oscilloscope may display waveforms of more than one channel within the same waveform display region, when a user wants to adjust a waveform of a certain channel, the waveform corresponding to the channel needs to be selected first. Generally, the user selects the target waveform through a finger touch or a mouse pointer click. In this case, the user must click on a position where the target waveform is separated from other waveforms on the display of the digital oscilloscope, preventing the finger or the mouse pointer from touching a region containing other waveforms. However, waveforms of multiple channels are typically displayed in an overlapping manner on the display of the digital oscilloscope with a limited display size. In many cases, it is difficult to find a large region that can distinguish the target waveform from other waveforms. Moreover, even if the two waveforms appear to be separated on the display, since both the finger touch and the mouse pointer click have a certain response region, multiple waveforms are touched when the user actually clicks to select. In this case, the digital oscilloscope may select a non-target waveform and respond incorrectly.

### SUMMARY

The present disclosure provides a waveform selection method, an electronic test and measurement device, and a storage medium to effectively identify the click intention of a user and improve the accuracy of waveform selection.

In a first aspect, a waveform selection method is provided and includes the following:

In response to a click operation of a user, a click position on a display is determined.

A waveform selection region is determined according to the click position.

Waveform energies of waveforms of multiple channels within the waveform selection region are respectively determined.

A target waveform is selected from the waveforms of the multiple channels according to the waveform energies of the waveforms of the multiple channels.

In one or more embodiments, the step in which the waveform selection region is determined according to the click position includes the following:

A display region containing the click position and having a preset calculation area is used as the waveform selection region.

In one or more embodiments, the click position is located at the center of the waveform selection region.

In one or more embodiments, the waveform selection region is circular or right-angled quadrilateral.

In one or more embodiments, the step in which the waveform energies of the waveforms of the multiple channels within the waveform selection region are respectively determined includes the following:

For the waveform of each channel contained in the waveform selection region, a waveform luminance area integral of the waveform of each channel within the waveform selection region is used as a waveform energy of the waveform of the respective channel.

In one or more embodiments, the step in which the target waveform is selected from the waveforms of the multiple channels according to the waveform energies of the waveforms of the multiple channels includes the following:

According to the waveform energies of the waveforms of the multiple channels, an energy proportion of the waveform of each channel within the waveform selection region is determined.

A waveform of a channel with the highest energy proportion is determined as the target waveform selected by the user.

In one or more embodiments, the click operation includes a click operation of touching the display and a click operation of a mouse.

In a second aspect, a waveform selection apparatus is provided and includes a click position determination module, a selection region determination module, a waveform energy statistics module, and a target waveform selection module.

The click position determination module is configured to determine a click position on a display in response to a click operation of a user.

The selection region determination module is configured to determine a waveform selection region according to the click position.

The waveform energy statistics module is configured to respectively determine waveform energies of waveforms of multiple channels within the waveform selection region.

The target waveform selection module is configured to select a target waveform from the waveforms of the multiple channels according to the waveform energies of the waveforms of the multiple channels.

In a third aspect, an electronic test and measurement device is provided and includes at least one processor and a memory communicatively connected to the at least one processor.

The memory stores a computer program executable by the at least one processor, and the computer program is executed by the at least one processor to enable the at least one processor to execute the waveform selection method described in the first aspect of the present disclosure.

In a fourth aspect, a computer-readable storage medium is provided and stores computer instructions. The computer instructions are configured to, when executed by a processor, cause the processor to implement the waveform selection method described in the first aspect of the present disclosure.

### BRIEF DESCRIPTION OF DRAWINGS

FIG. 1 is a flowchart of a waveform selection method according to embodiment one of the present disclosure.

FIGS. 2A to 2D are examples illustrating the waveform selection region according to embodiment one of the present disclosure.

FIG. 3 is a schematic diagram of the principle of a waveform selection method according to embodiment one of the present disclosure.

FIG. 4 is a schematic structural diagram of a waveform selection apparatus according to embodiment two of the present disclosure.

FIG. 5 is a schematic structural diagram of an electronic test and measurement device for implementing the waveform selection method in the embodiments of the present disclosure.

### DETAILED DESCRIPTION

To enable those skilled in the art to better understand the solutions of the present disclosure, the solutions in the embodiments of the present disclosure are described clearly and completely hereinafter in conjunction with the drawings in the embodiments of the present disclosure.

It should be noted that the terms “first” and “second” in the description, claims and the above drawings of the present disclosure are used to distinguish similar objects, and are not necessarily used to describe a specific order or sequence. It should be understood that the numbers used in this way may be interchanged where appropriate, so that the embodiments of the present disclosure described herein may be implemented in an order other than those illustrated or described herein. Furthermore, the terms “including” and “comprising” and any variations thereof are intended to cover non-exclusive inclusion, for example, a process, method, system, product or device that includes a series of steps or elements is not necessarily limited to those steps or elements expressly listed, but may include other steps or elements not expressly listed or inherent to such process, method, product or device.

### Embodiment One

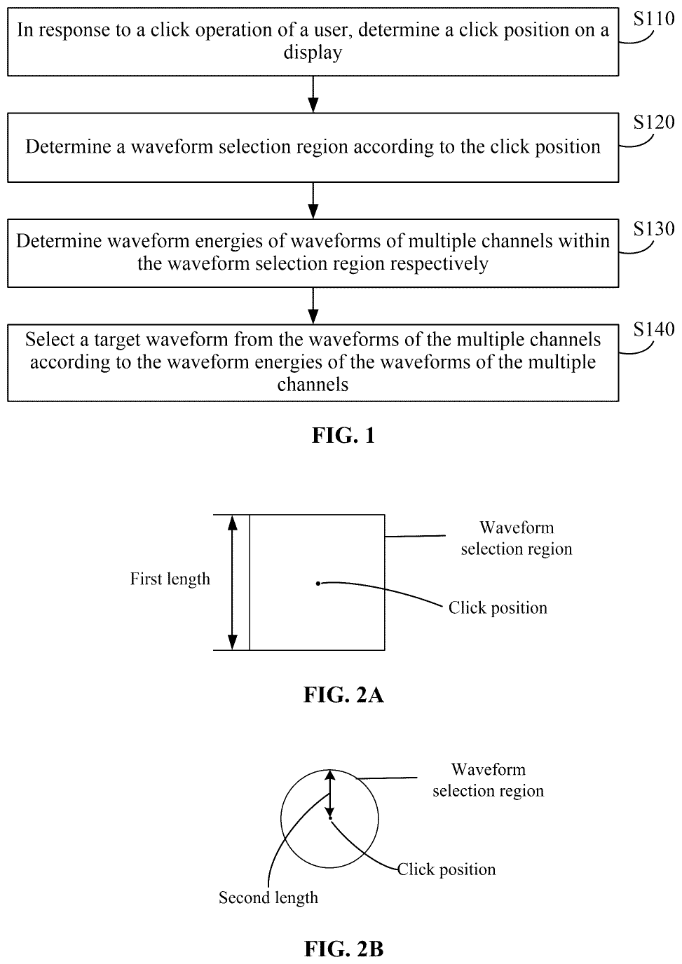

FIG. 1 is a flowchart of a waveform selection method according to embodiment one of the present disclosure. The present embodiment is applicable to the case where one waveform among multiple waveforms displayed on a display of an electronic test and measurement device is clicked for selection. The waveform selection method may be executed by a waveform selection apparatus. The waveform selection apparatus may be implemented in hardware and/or software and may be configured in the electronic test and measurement device. As shown in FIG. 1, the waveform selection method includes S110 to S140.

In S110, in response to a click operation of a user, a click position on a display is determined.

The waveform selection method provided in the embodiment is applicable to the electronic test and measurement device, such as the digital oscilloscope and other electronic devices. The case where a user selects one of the waveforms of the channels displayed on the display of the electronic test and measurement device is taken as an example in the embodiment.

In this embodiment, waveforms corresponding to multiple channels are displayed on the display of the electronic test and measurement device, and when the user wants to select a waveform of a certain channel, a corresponding click operation may be performed. When receiving the click operation of the user, the electronic test and measurement device may record the click position on the display.

In an embodiment, the click operation may include a click operation of touching the display and a click operation of a mouse.

In practical application, the user may directly touch the display to perform the click operation, including touching the display with a finger or touching the display with a stylus. When the user touches the display to perform the click operation, the position of a contact point between the finger and the display may be taken as the click position. Alternatively, the position of the contact point between the tip of the stylus and the display may be taken as the click position. When the display is a capacitive screen, the touch position of the user may be determined by measuring the capacitance variation of the capacitive screen, and the coordinate of the click position may be calculated according to the timing of the touch event. When the display is a resistive screen, the touch position of the user may be detected by a resistance variation between two conductive films. When the display is an infrared touch screen, the touch position may be detected by emitting and receiving an infrared light beam; when the touch occurs, the light beam is blocked, thus determining the click position.

The user may also use a mouse to click on the display. The user may move the mouse pointer on the display accordingly by moving the mouse. When the user clicks the mouse, the position of the mouse pointer is taken as the click position.

It can be understood that the click operation in the present embodiment is not limited to the click operation of touching the display and the click operation of the mouse. The waveform selection method of the embodiment can respond to the click operations that can be supported by other technologies.

In S120, a waveform selection region is determined according to the click position.

In the embodiment, to reduce the probability of incorrect waveform selection caused by crowded display on the display and deviation in the click operation of the user, instead of determining the waveform selection by simply using the click position, the waveform selection region associated with the click position is used to comprehensively determine which waveform of a channel in the display is more inclined to the selection intention of the user.

In an embodiment, S120 may be implemented in the following manner:

A display region containing the click position and having a preset calculation area is used as the waveform selection region.

In practical application, the area size of the waveform selection region may be determined according to the usage scenario. After the click position is determined, a region near the click position with the preset calculation area is recorded as the waveform selection region.

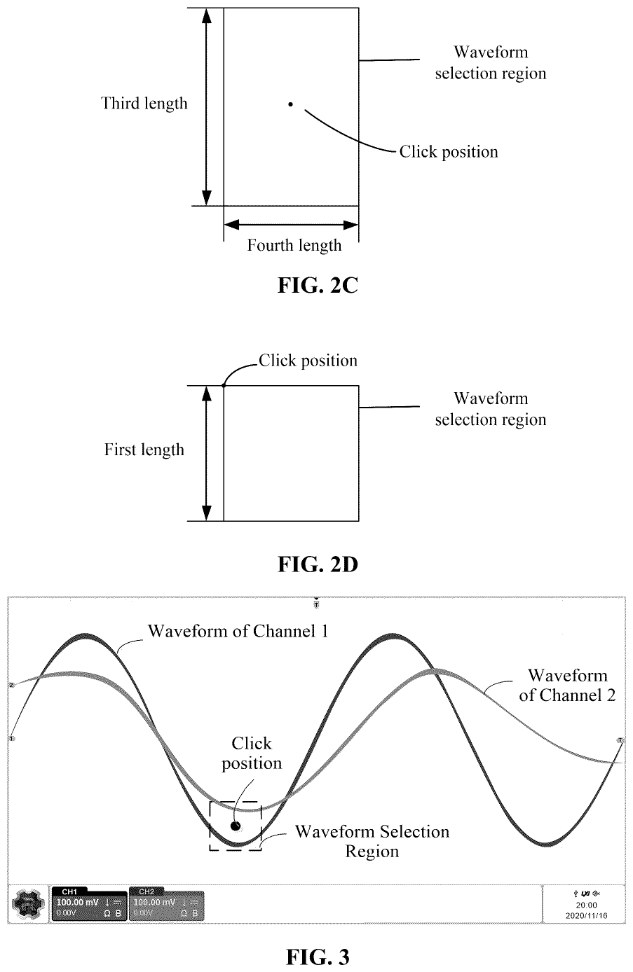

Exemplarily, as shown in FIGS. 2A to 2C, the click position is located at the center of the waveform selection region. As shown in FIGS. 2A to 2D, the waveform selection region is circular or right-angled quadrilateral.

Generally, although deviation in the position where the user clicks on the display may exist, the click position may substantially reflect the approximate position of the waveform that the user wants to select. Therefore, the waveform selection region is determined by taking the click position as the center so that the probability of correct waveform selection can be improved. Generally, for ease of calculation, the waveform selection region may be circular or right-angled quadrilateral.

It can be understood that the click position may also be located at any position within the waveform selection region, for example, at a vertex or an edge of a right quadrilateral.

In a specific example, as shown in FIG. 2A, a square with the click position as the center and a first length as the side length may be determined as the waveform selection region. Alternatively, as shown in FIG. 2B, a circle with the click position as the center and a second length as the radius may be determined as the waveform selection region. Alternatively, as shown in FIG. 2C, a rectangle with the click position as the center, a third length as the long edge, and a fourth length as the short edge may be determined as the waveform selection region. Alternatively, as shown in FIG. 2D, a square with the click position as the vertex in the top-left corner and the first length as the side length may be determined as the waveform selection region.

In S130, waveform energies of waveforms of multiple channels within the waveform selection region are determined.

In the embodiment, the waveform energy corresponding to the waveform of each channel contained within the waveform selection region may be statistically analyzed, thus reflecting the distribution of the waveforms of the multiple channels within the waveform selection region.

In an embodiment, S130 may be implemented in the following manner:

For the waveform of each channel contained in the waveform selection region, a waveform luminance area integral of the waveform of each channel within the waveform selection region is used as the waveform energy of the waveform of the respective channel.

Exemplarily, the waveform energy of a waveform of a channel within the waveform selection region may refer to a sum of the luminance of each waveform point that constitutes this waveform of the channel within the waveform selection region, that is, the integral of the waveform luminance and area within the waveform selection region, which may be roughly expressed as follows:

$$Waveform energy = \sum Waveform point luminance = \int Waveform luminance * Area .$$

In S140, a target waveform is selected from the waveforms of the multiple channels according to the waveform energies of the waveforms of the multiple channels.

In the embodiment, the waveform energy of the waveform of the channel may reflect the distribution of the waveform of the channel within the waveform selection region. Therefore, the target waveform with the selection intention of the user may be selected by analyzing the waveform energy of the waveform of each channel.

In an embodiment, S140 may be implemented in the following manner:

According to the waveform energies of the waveforms of the multiple channels, an energy proportion of the waveform of each channel within the waveform selection region is determined. The waveform of a channel with the highest energy proportion is determined as the target waveform selected by the user.

It can be understood that when the waveform of a channel has a higher energy proportion within the waveform selection region, it may indicate that the user is more inclined to select this waveform of the channel when clicking on the click position. Therefore, the waveform of the channel with the highest energy proportion within the waveform selection region may be determined as the target waveform selected by the user.

Specifically, when the waveform energies of the waveforms of the multiple channels within the waveform selection region are lower than a preset energy threshold, the click operation of the user may be considered a mis-operation, none of the waveforms of these channels may be selected, and a corresponding prompt may be shown on the display.

FIG. 3 is a schematic diagram of the principle of a waveform selection method according to embodiment one of the present disclosure. As shown in FIG. 3, the waveform of channel 1 and the waveform of channel 2 are simultaneously displayed by the display of the electronic test and measurement device, which are relatively close in distance. When the user wants to select the waveform of channel 1, the user touches the display with the finger or clicks the display with the mouse, and the black dot in the figure indicates the click position of the user. Taking the click position as the center, a display region with the preset calculation area is defined as the waveform selection region, as shown by the dashed-line box in the figure. It may be determined that the energy proportion of the waveform of channel 1 is higher than the energy proportion of the waveform of channel 2 by calculating the waveform energies of the waveform of channel 1 and the waveform of channel 2 within the dashed-line box. Therefore, the waveform of channel 1 is selected as the target waveform.

According to the technical solution of an embodiment of the present disclosure, in response to the click operation of the user, the click position on the display is determined. The waveform selection region is determined according to the click position. The waveform energies of the waveforms of the multiple channels within the waveform selection region are determined. The target waveform is selected from the waveforms of the multiple channels according to the waveform energies of the waveforms of the multiple channels. According to the embodiment of the present disclosure, the problem that when the display simultaneously displays waveforms of multiple channels, the user cannot correctly select the required waveform due to a waveform overlap and a blurred user click region can be avoided. The click intention of the user can be effectively identified when the user selects the waveform, and the accuracy of the waveform selection can be improved.

### Embodiment Two

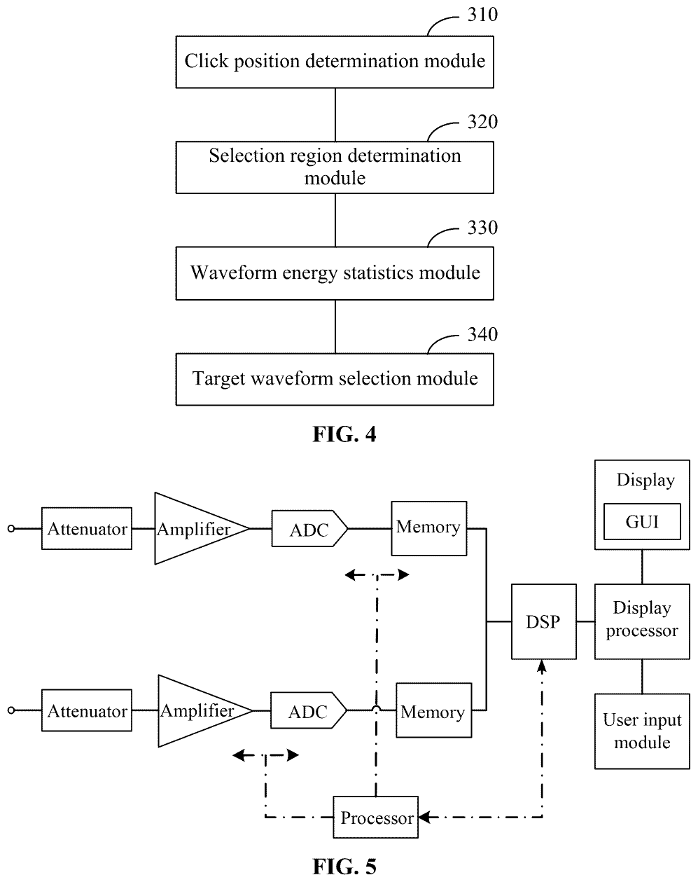

FIG. 4 is a schematic structural diagram of a waveform selection apparatus provided in embodiment two of the present disclosure. As shown in FIG. 4, the waveform selection apparatus includes a click position determination module 310, a selection region determination module 320, a waveform energy statistics module 330, and a target waveform selection module 340.

The click position determination module 310 is configured to determine a click position on a display in response to a click operation of a user.

The selection region determination module 320 is configured to determine a waveform selection region according to the click position.

The waveform energy statistics module 330 is configured to respectively determine waveform energies of waveforms of multiple channels within the waveform selection region.

The target waveform selection module 340 is configured to select a target waveform from the waveforms of the multiple channels according to the waveform energies of the waveforms of the multiple channels.

In one or more embodiments, the selection region determination module 320 is configured to use a display region containing the click position and having a preset calculation area as the waveform selection region.

In one or more embodiments, the click position is located at the center of the waveform selection region.

In one or more embodiments, the waveform selection region is circular or right-angled quadrilateral.

In one or more embodiments, the waveform energy statistics module 330 is configured as follows:

For a waveform of each channel contained in the waveform selection region, a waveform luminance area integral of the waveform of each channel within the waveform selection region is used as a waveform energy of the waveform of the respective channel.

In one or more embodiments, the target waveform selection module 340 is configured to determine an energy proportion of the waveform of each channel within the waveform selection region according to the waveform energies of the waveforms of the multiple channels, and determine a waveform of a channel with the highest energy proportion as the target waveform selected by the user.

In one or more embodiments, the click operation includes a click operation of touching the display and a click operation of a mouse.

The waveform selection apparatus provided by the embodiment of the present disclosure may execute the waveform selection method provided by any embodiment of the present disclosure, and has corresponding functional modules for executing the method.

### Embodiment Three

FIG. 5 shows a schematic structural diagram of an electronic test and measurement device that may be used to implement the embodiment of the present disclosure. The electronic test and measurement device of this embodiment may be a digital oscilloscope.

The electronic test and measurement device may include at least one signal channel, and this embodiment takes two signal channels as an example. As shown in FIG. 5, a first channel of the electronic test and measurement device is configured to receive a first signal through a first port, and a second channel is configured to receive a second signal through a second port. The first channel and the second channel each include an attenuator, an amplifier and an analog-to-digital converter (ADC). The attenuator is configured to reduce the signal power input to the electronic test and measurement device, that is, to attenuate the input signal to the working range of the amplifier. The amplifier is configured to amplify or attenuate a signal, that is, amplify or attenuate the input signal to the full-scale range of the ADC. The ADC is configured to digitize the signal output by the amplifier at a predetermined sampling rate to acquire a waveform of the signal input from the first channel and/or the second channel. Data of the digitized waveform is stored in a memory and output from the memory to a digital signal processor (DSP) for processing.

The electronic test and measurement device includes at least one processor and a memory, such as a read-only memory (ROM), a random access memory (RAM), and the like, communicatively connected to the at least one processor. The memory stores a computer program executable by the at least one processor. The processor may perform various appropriate actions and processes according to the computer programs stored in the ROM or loaded from a storage unit into the RAM. Various programs and data required for the operation of the electronic test and measurement device may also be stored in the RAM. The processor, the ROM and the RAM are connected to each other through a bus. The processor may be various general-purpose and/or special-purpose processing components with processing and computing capabilities. Some examples of the processor include, but are not limited to, a central processing unit (CPU), a graphics processing unit (GPU), various special-purpose artificial intelligence (AI) computing chips, various processors running machine learning model algorithms, a DSP, and any other suitable processor, controller, microcontroller, etc. The processor executes various methods and processes described above, such as the waveform selection method.

The processor executes the control operation of the electronic test and measurement device and is configured to control the conditioning, acquisition and display of the first signal waveform received from the first channel and the second signal waveform received from the second channel. When the electronic test and measurement device is the digital oscilloscope, the processor further includes a trigger control module. The trigger control module is configured to control the signal triggering to display the waveform. The trigger control module is also configured to control the horizontal time base, vertical level and offset of the display to display the waveform appropriately.

The DSP receives and processes the digital signals stored in the memory and provided by the first channel and the second channel to reconstruct the original input signal for display.

The electronic test and measurement device further includes a display processor, a user input module, and a display. The user input module is configured to receive information and data input by the user. The display processor is configured to receive the data input by the user, process the waveform data, and display the waveforms of the first channel and/or the second channel on the display through a graphical user interface (GUI). The user input module may include a mouse, a keyboard, a trackball, a joystick, and a touch pad. The display may include a light-emitting diode (LED) display, an organic light-emitting diode (OLED) display, etc. In an embodiment, the user input module is a touch screen, and the user input module is disposed on the display in this case.

The components shown herein, their connections and relationships, and their functions are merely examples, and are not intended to limit the implementation of the present disclosure as described and/or claimed herein.

In some embodiments, the waveform selection method may be implemented as a computer program tangibly embodied in a computer-readable storage medium, such as the storage unit. In some embodiments, part or all of the computer program may be loaded and/or installed on the electronic device via a ROM and/or a communication unit. When the computer program is loaded into the RAM and executed by the processor, one or more steps of the waveform selection method described above may be executed. Alternatively, in other embodiments, the processor may be configured to execute the waveform selection method by any other suitable means (e.g., by means of firmware).

Various embodiments of the systems and techniques described above herein may be implemented in digital electronic circuitry, integrated circuit systems, field-programmable gate arrays (FPGA), application specific integrated circuits (ASIC), application specific standard parts (ASSP), system-on-chip system (SOC), complex programmable logic devices (CPLD), computer hardware, firmware, software, and/or combinations thereof. These various embodiments may include being implemented in one or more computer programs, one or more computer programs are executed and/or interpreted on a programmable system including at least one programmable processor, the at least one programmable processor may be a special-purpose or general-purpose programmable processor that may receive data and instructions from a storage system, at least one input device, and at least one output device, and transmit the data and instructions to the storage system, the at least one input device, and the at least one output device.

The computer program for implementing the method of the present application may be written in any combination of one or more programming languages. These computer programs may be provided to a processor of a general-purpose computer, a special-purpose computer or other programmable data processing apparatus, so that when the computer program is executed by the processor, the functions/operations specified in the flowcharts and/or block diagrams are implemented. The computer program may be executed entirely on a machine, partially executed on a machine, partially executed on a machine and partially executed on a remote machine as an independent software package, or executed entirely on a remote machine or server.

In the context of the present application, a computer-readable storage medium may be a tangible medium, which may contain or store a computer program for use by or in combination with an instruction execution system, apparatus or device. The computer-readable storage medium may include, but is not limited to, an electronic, magnetic, optical, electromagnetic, infrared, or semiconductor system, apparatus or device, or any suitable combination of the foregoing. Alternatively, the computer-readable storage medium may be a machine-readable signal medium. More specific examples of the machine-readable storage medium may include an electrical connection according to one or more wires, a portable computer disk, a hard disk, a RAM, a ROM, an erasable programmable read-only memory (EPROM or flash memory), an optical fiber, a portable compact disc read-only memory (CD-ROM), an optical storage device, a magnetic storage device, or any suitable combination of the foregoing.

To provide interaction with a user, the systems and techniques described herein may be implemented on an electronic device, and the electronic device has the following: a display device (e.g., a cathode ray tube (CRT) or liquid crystal display (LCD) monitor) for displaying information to the user; and a keyboard and a pointing device (e.g., a mouse or trackball) through which the user may provide input to the electronic device. Other types of devices may also be used to provide interaction with the user; for example, the feedback provided to the user may be any form of sensory feedback (e.g., visual feedback, auditory feedback, or tactile feedback), and the input from the user may be received in any form (including acoustic input, voice input or tactile input).

The systems and techniques described herein may be implemented in a computing system that includes a back-end component (e.g., as a data server), or a computing system that includes a middleware component (e.g., an application server), or a computing system that includes a front-end component (e.g., a user computer with a graphical user interface or a web browser through which a user can interact with implementations of the systems and techniques described herein), or a computing system that includes any combination of such back-end components, middleware components, or front-end components. The components of the system may be interconnected in any form or medium of digital data communication (e.g., a communication network). Examples of communication networks include a local area network (LAN), a wide area network (WAN), a blockchain network, and the Internet.

A computing system may include a client and a server. The client and server are generally far from each other and usually interact through a communication network. The relationship between client and server is generated by computer programs running on corresponding computers and having a client-server relationship. The server may be a cloud server, also known as a cloud computing server or cloud host. The cloud server is a host product in the cloud computing service system to solve the defects of large management difficulty and weak business scalability existing in the traditional physical host and virtual private server (VPS) services.

It should be understood that various forms of processes shown above may be used, and steps may be reordered, added, or deleted. For example, the steps described in the present application may be executed in parallel, sequentially or in a different order, so long as the desired result of the technical solution of the present application can be achieved, no limitation is made herein.

What is claimed is:

1. A waveform selection method, comprising:
in response to a click operation of a user, determining a click position on a display;
determining a waveform selection region according to the click position;
determining waveform energies of waveforms of a plurality of channels within the waveform selection region, respectively; and
selecting a target waveform from the waveforms of the plurality of channels according to the waveform energies of the waveforms of the plurality of channels.

2. The waveform selection method according to claim 1, wherein determining the waveform selection region according to the click position comprises:
using a display region containing the click position and having a preset calculation area as the waveform selection region.

3. The waveform selection method according to claim 2, wherein
the click position is located at a center of the waveform selection region.

4. The waveform selection method according to claim 2, wherein
the waveform selection region is circular or right-angled quadrilateral.

5. The waveform selection method according to claim 3, wherein
the waveform selection region is a square with a first length as a side length of the square.

6. The waveform selection method according to claim 3, wherein
the waveform selection region is a circle with a second length as a radius of the circle.

7. The waveform selection method according to claim 3, wherein
the waveform selection region is a rectangle with a third length as a long edge of the rectangle and a fourth length as a short edge of the rectangle.

8. The waveform selection method according to claim 2, wherein
the waveform selection region is a square with the click position as a vertex of the square and a first length as a side length of the square.

9. The waveform selection method according to claim 1, wherein determining the waveform energies of the waveforms of the plurality of channels within the waveform selection region respectively comprises:
for a waveform of each channel among the waveforms of the plurality of channels contained in the waveform selection region, using a waveform luminance area integral of the waveform of each channel within the waveform selection region as a waveform energy of the waveform of the respective channel.

10. The waveform selection method according to claim 1, wherein selecting the target waveform from the waveforms of the plurality of channels according to the waveform energies of the waveforms of the plurality of channels comprises:
determining, according to the waveform energies of the waveforms of the plurality of channels, an energy proportion of a waveform of each channel among the waveforms of the plurality of channels within the waveform selection region; and
determining a waveform of a channel with a highest energy proportion among the waveforms of the plurality of channels as the target waveform selected by the user.

11. The waveform selection method according to claim 1, further comprising:
in response to each waveform energy among the waveform energies of the waveforms of the plurality of channels within the waveform selection region being lower than a preset energy threshold, determining the click position as a mis-operation, and not performing selecting the target waveform from the waveforms of the plurality of channels.

12. The waveform selection method according to claim 1, wherein
the click operation comprises a click operation of touching the display and a click operation of a mouse.

13. An electronic test and measurement device, comprising:
at least one processor; and
a memory communicatively connected to the at least one processor; wherein
the memory stores a computer program executable by the at least one processor, and the computer program is executed by the at least one processor to enable the at least one processor to execute a waveform selection method, wherein the waveform selection method comprises:
in response to a click operation of a user, determining a click position on a display;
determining a waveform selection region according to the click position;
determining waveform energies of waveforms of a plurality of channels within the waveform selection region, respectively; and
selecting a target waveform from the waveforms of the plurality of channels according to the waveform energies of the waveforms of the plurality of channels.

14. The electronic test and measurement device according to claim 13, wherein determining the waveform selection region according to the click position comprises:
using a display region containing the click position and having a preset calculation area as the waveform selection region.

15. The electronic test and measurement device according to claim 14, wherein
the click position is located at a center of the waveform selection region.

16. The electronic test and measurement device according to claim 14, wherein
the waveform selection region is circular or right-angled quadrilateral.

17. The electronic test and measurement device according to claim 15, wherein
the waveform selection region is a square with a first length as a side length of the square.

18. The electronic test and measurement device according to claim 15, wherein
the waveform selection region is a circle with a second length as a radius of the circle.

19. The electronic test and measurement device according to claim 15, wherein
the waveform selection region is a rectangle with a third length as a long edge of the rectangle and a fourth length as a short edge of the rectangle.

20. A non-transitory computer-readable storage medium storing computer instructions, wherein the computer instructions are configured to, when executed by a processor, cause the processor to implement a waveform selection method, wherein the waveform selection method comprises:
in response to a click operation of a user, determining a click position on a display;
determining a waveform selection region according to the click position;
determining waveform energies of waveforms of a plurality of channels within the waveform selection region, respectively; and
selecting a target waveform from the waveforms of the plurality of channels according to the waveform energies of the waveforms of the plurality of channels.
